(19) United States
(12) Patent Application Publication
(10) Pub. No.: US 2013/0323864 A1
(43) Pub. Date: Dec. 5, 2013

(54) SEMICONDUCTOR TEST EQUIPMENT AND METHOD OF TESTING AND MANUFACTURING SEMICONDUCTOR DEVICES USING THE SAME

(71) Applicant: SAMSUNG ELECTRONICS CO., LTD., Suwon-si (KR)

(72) Inventors: Jae-Bum Mo, Hwaseong-si (KR); Byoung-Joo Kim, Hwaseong-si (KR); Jin-Su Kim, Jinju-si (KR)

(73) Assignee: SAMSUNG ELECTRONICS CO., LTD., Suwon-si (KR)

(21) Appl. No.: 13/761,157

(22) Filed: Feb. 7, 2013

(30) Foreign Application Priority Data
Jun. 5, 2012 (KR) 10-2012-0060479

(51) Int. Cl. H01L 21/66; G01R 31/26

(52) U.S. Cl. CPC H01L 22/14; G01R 31/2601
USPC 438/17; 324/750.16

(57) ABSTRACT

A method of manufacturing a semiconductor device including a substrate is disclosed. The method includes: providing the substrate on a wafer chuck; positioning a probe card having probe needles above the substrate; positioning a tester head above the probe card; using a sensor included in the tester head, measuring a deformation of the probe card; using a variable load device included in the tester head, adjusting the deformation of the probe card based on the measured deformation; and testing the substrate using the adjusted probe card.

This application claims priority to Korean Patent Application No. 10-2012-0060479 filed on Jun. 5, 2012 in the Korean Intellectual Property Office, the disclosure of which is incorporated herein by reference in its entirety.

### BACKGROUND

1. Field

The present disclosure relates to semiconductor device test equipment and a method of testing and manufacturing semiconductor devices using the same.

2. Description of the Related Art

As semiconductor devices become lighter, thinner, shorter and smaller, it has become important to test the semiconductor devices in a stable manner. For stable testing of semiconductor devices, a contact force between the semiconductor devices and test equipment is very important. Therefore, various research is being conducted to provide a stable contact force between semiconductor devices and test equipment.

In a semiconductor process, an electric die sorting (EDS) process is performed in order to test operation characteristics of individual chips (fabricated on the FAB line) on a substrate and repair defective chips. Since a large number of chips are measured simultaneously in the EDS process, contact reliability between the fabricated chips on the substrate and probe needles is important.

### SUMMARY

Aspects of the present disclosure provide semiconductor test equipment which can improve contact reliability between a probe card and a substrate using a variable load device which can adjust deformation of the probe card.

Aspects of the present disclosure also provide a method of testing characteristics of semiconductor devices and manufacturing semiconductor devices using the above semiconductor test equipment.

However, aspects of the present invention are not restricted to the examples set forth herein. The above and other aspects of the present invention will become more apparent to one of ordinary skill in the art to which the present disclosure pertains by referencing the various embodiments in the detailed description given below.

According to one embodiment, method of manufacturing a semiconductor device including a substrate is disclosed. The method includes: providing the substrate on a wafer chuck; positioning a probe card having probe needles above the substrate; positioning a tester head above the probe card; using a sensor included in the tester head, measuring a deformation of the probe card; using a variable load device included in the tester head, adjusting the deformation of the probe card based on the measured deformation; and testing the substrate using the adjusted probe card.

According to another embodiment, a method of manufacturing a semiconductor device is disclosed. The method includes placing a substrate used to form the semiconductor device on a wafer chuck; positioning a probe card having probe needles above the substrate; positioning a tester head above the probe card; using a sensor disposed above the probe card, measuring a deformation of the probe card; using a variable load device disposed above the probe card, and based on the measurement, causing the probe card to be substantially flat; testing the substrate using the substantially flat probe card; and forming the semiconductor device after testing of the substrate is complete.

According to another embodiment, semiconductor test equipment is disclosed. The equipment includes a wafer chuck configured to support on which a substrate to be tested is mounted thereon; a probe card placed above the wafer chuck and comprising probe needles which configured to provide a test signal to the substrate; a sensor placed above the probe card and configured to measure measuring deformation of the probe card; and a variable load device configured to adjusting the deformation of the probe card based on a measurement of the deformation of the probe card by being linked with the sensor.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary side view of semiconductor test equipment according to one embodiment;

FIG. 2 is an exemplary side view of a portion I of FIG. 1 when a tester head is docked with a probe card, according to one embodiment;

FIGS. 3 through 4B are diagrams illustrating an exemplary process of measuring deformation of the probe card using a sensor, according to certain embodiments;

FIGS. 5A and 5B are diagrams illustrating an exemplary operation of a variable load device, according to certain embodiments;

FIG. 6 is an exemplary side view of semiconductor test equipment according to another embodiment;

FIG. 7 is a flowchart illustrating an exemplary method of testing semiconductor devices according to one embodiment; and

FIGS. 8A and 8B are exemplary side views illustrating intermediate processes included in the test method of FIG. 7, according to one embodiment;

FIG. 9 is a flowchart illustrating an exemplary method of manufacturing a semiconductor device according to one embodiment.

### DETAILED DESCRIPTION

The present disclosure will now be described more fully hereinafter with reference to the accompanying drawings, in which various embodiments are shown. However, this invention may be embodied in different forms and should not be construed as limited to the embodiments set forth herein. The same reference numbers indicate the same or similar components throughout the specification. In the attached figures, the thickness of layers and regions is exaggerated for clarity.

It will be understood that when an element or layer is referred to as being “connected to,” or “coupled to” another element or layer, it can be directly connected to or on or coupled to another element or layer or intervening elements or layers may be present. In contrast, when an element is referred to as being “directly connected to” “contacting,” or “directly coupled to” another element or layer, for at least part of the two elements or layers, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

The use of the terms “a” and “an” and “the” and similar referents in the context of describing the various embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures have schematic properties, and shapes of regions shown in figures exemplify specific shapes of regions of elements, and the specific properties and shapes do not limit aspects of the invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries should not be overly interpreted.

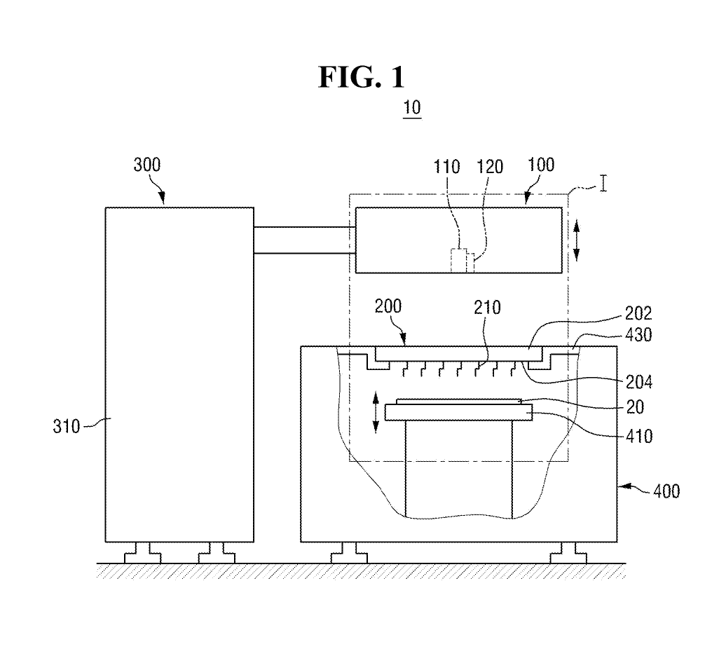

Semiconductor test equipment according to one exemplary embodiment will now be described with reference to FIGS. 1 through 5B.

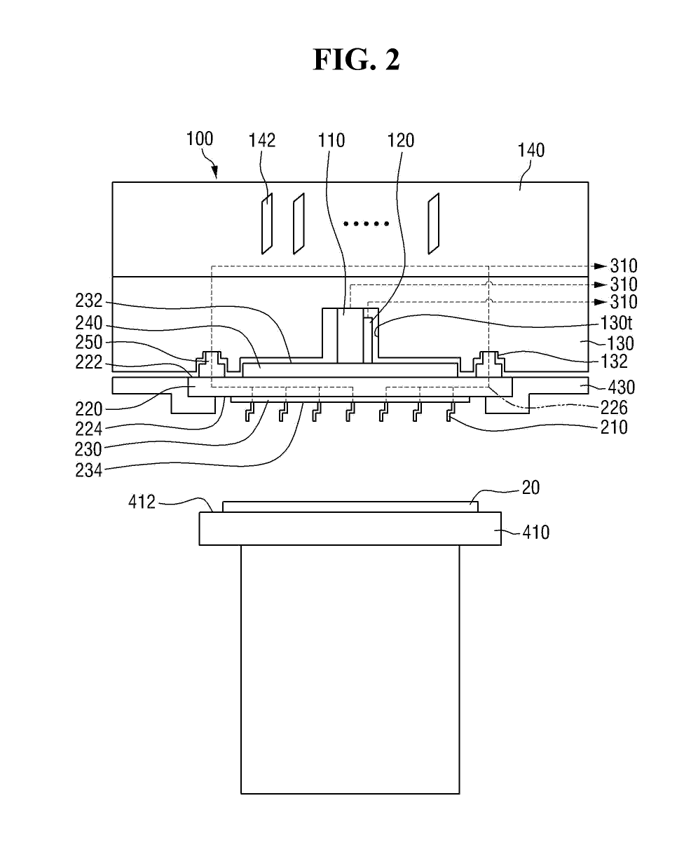

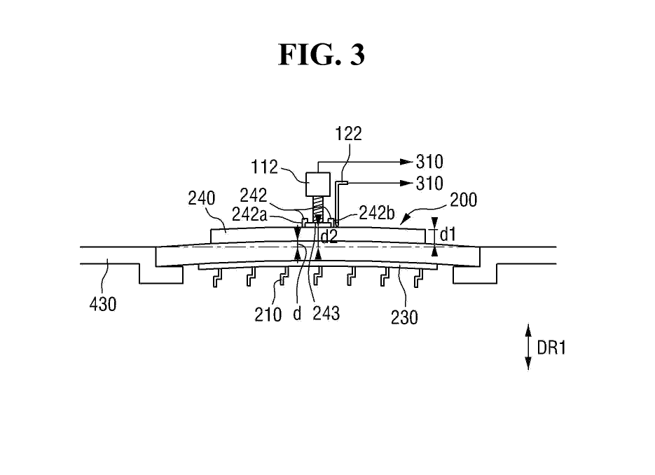

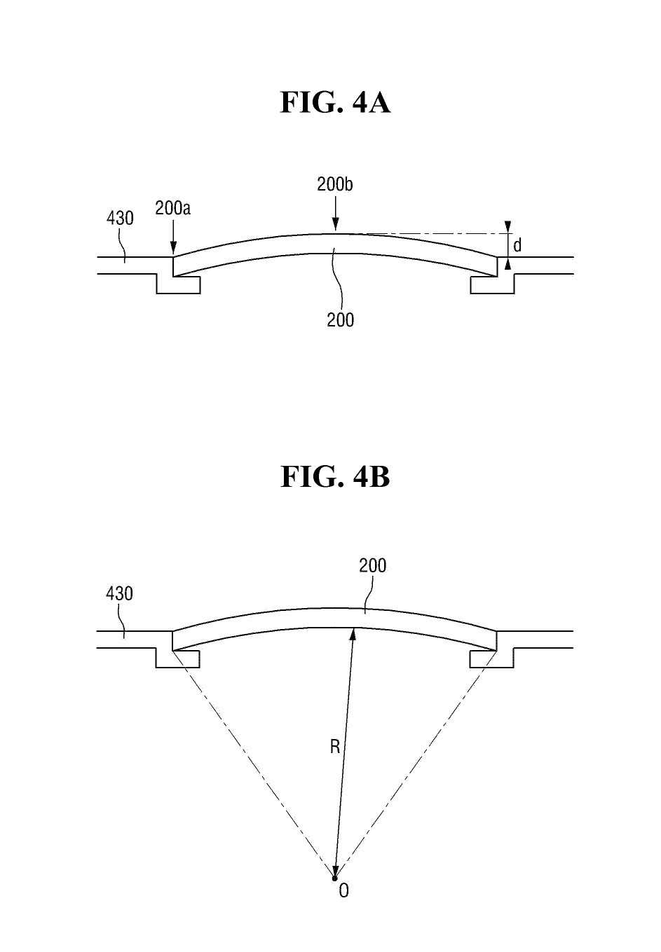

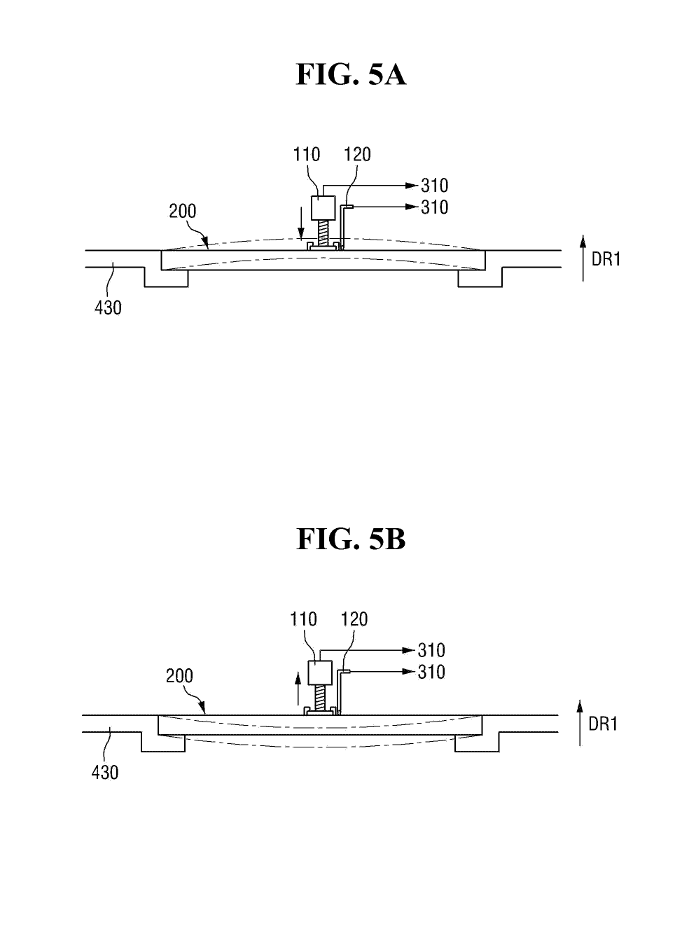

FIG. 1 is an exemplary side view of semiconductor test equipment 10 according to one embodiment. FIG. 2 is an exemplary side view of a portion I of FIG. 1 when a tester head 100 is docked with a probe card 200. FIGS. 3 through 4B are diagrams illustrating an exemplary process of measuring deformation of the probe card 200 using a sensor 120. FIGS. 5A and 5B are diagrams illustrating an exemplary operation of a variable load device 110.

Referring to FIG. 1, the semiconductor test equipment 10 according to one embodiment includes a tester 300, a prober 400, the sensor 120, the variable load device 110, and the probe card 200. The tester 300 may generate a predetermined electrical signal for testing semiconductor devices and transmit the generated electrical signal to each of the semiconductor devices. The prober 400 may move a substrate 20 to be tested, so that the tester 300 can test the substrate 20. The probe card 200 may serve as a medium for delivering a signal generated by the tester 300 to semiconductor devices formed on the substrate 20. The sensor 120 may measure deformation of the probe card 200, and the variable load device 110 may provide a load to adjust the deformation of the probe card 200. In the drawing, the sensor 120 is located within the tester head 100. However, the position of the sensor 120 is not limited to the above position. The probe card 200, the sensor 120 and the variable load device 110 will be described later with reference to FIG. 2.

Specifically, the tester 300 may consist of a test body 310 and the tester head 100 which ascends or descends a predetermined distance along the test body 310.

The test body 310 controls the overall process of testing semiconductor devices and determines whether the semiconductor devices are defective. For example, the test body 310 generates a test signal for testing semiconductor devices and transmits the generated test signal to the tester head 100. In addition, the test body 310 senses signals received in response to the test signal and determines whether the semiconductor devices are defective based on the sensed signals. Also, the test body 310 may receive measurement information from the sensor 120, and may transmit a deformation signal of the probe card 200 measured by the sensor 120 to the variable load device 110. In some cases, the test body 310 may analyze the deformation signal of the probe card 200 and transmit the analysis result to the variable load device 110.

The tester head 100 ascends or descends along the test body 310 and may optionally be docked with the probe card 200. Therefore, a test signal transmitted from the test body 310 is delivered to the probe card 200 via the tester head 100. The specific structure of the tester head 100 will be described later with reference to FIG. 2.

The prober 400 is disposed under the tester head 100 to receive a test signal from the tester 300. In one embodiment, a head plate 430 on which the probe card 200 can be placed is provided in an upper part of the prober 400. In addition, a wafer chuck 410 on which the substrate 20 is mounted is provided within the prober 400, specifically, under the head plate 430. The wafer chuck 410 fixes the substrate 20 to a top surface thereof using a method such as vacuum absorption and transfers the substrate 20 in a direction in which the test process proceeds. For example, the wafer chuck 410 may transfer the substrate 20 fixed to the top surface thereof to a position where a test will be performed. A surface having a predetermined roughness, for example, sand paper (not shown) may be provided on a surface of the wafer chuck 410. Therefore, when an end of any of probe needles 210 of the probe card 200 is stained with, e.g., foreign matter, it may be sanded with the surface (such as sandpaper) having the predetermined roughness to remove the foreign matter.

Referring to FIG. 2, the probe card 200 is placed above the wafer chuck 410 on which the substrate 20 is mounted. The probe card 200 includes the probe needles 210 which transmit a test signal to the substrate 20. The variable load device 110 may be placed on the probe card 200. The variable load device 110 may be linked with the sensor 120 and adjust the deformation of the probe card 200 in linkage with the sensor 120. For example, the variable load device may be electronically linked with the sensor 120 so that sensor information received from the sensor 120 is used to control the variable load device 110. The sensor 120 may measure the deformation of the probe card 200 and may be placed on the probe card 200. The position of the sensor 120 is not limited to the above position and can vary.

Specifically, the probe card 200 includes a probe substrate 220, the probe needles 210, a first stiffener 230, a second stiffener 240, and coupling pins 250.

The probe card 200 is located above the wafer chuck 410 and mounted on the head plate 430. The head plate 430 may be shaped like, e.g., a stepped ring having a through hole therein, and the probe card 200 may be mounted on this head plate 430. A portion of the probe card 200 which is actually mounted on the head plate 430 may be, but is not limited to, the probe substrate 220 of the probe card 200. The first stiffener 230 and the probe needles 210 may be exposed through the through hole formed in the head plate 430.

The probe card 200 includes a first surface 204 (see FIG. 1) and a second surface 202 (see FIG. 1) which are located opposite each other, and the probe substrate 220 may include a first surface 224 and a second surface 222 which are located opposite each other. If no stiffeners 230 or 240 are used, it may be assumed that the first surface 204 of the probe card 200 corresponds to the first surface 224 of the probe substrate 220 and that the second surface 202 of the probe card 200 corresponds to the second surface 222 of the probe substrate 220. Specifically, the first surface 224 of the probe substrate 220 is a surface that faces the wafer chuck 410, and the probe needles 210 may be provided on and may contact the first surface 224. The variable load device 110 may be placed on and may contact the second surface 222 of the probe substrate 220 which is opposite the first surface 224. If stiffeners 230 and 240 are used, then the surface of the probe card 200 may correspond to the surfaces of the probe substrate 220 where it is not covered with a stiffener, and the surfaces of the stiffeners 230 and 240 where the probe substrate 220 is covered with a stiffener. In this embodiment, probe needles may be provided on the first surface 204 of the probe card 200, and may contact a surface 234 of the first stiffener 230. The variable load device 110 may be placed on the second surface 202 of the probe card 200, and may contact surface 232 of the second stiffener 240.

The probe substrate 220 may have a shape, e.g., a disc shape that enables the probe substrate 220 to be mounted on the head plate 430. A plurality of signal lines 226 are formed inside the probe substrate 220. The signal lines 226 deliver a test signal generated and transmitted from the test body 310 to the probe needles 210. To this end, a signal line 226 may extend from above the probe substrate 220 through the probe substrate 220 to under the probe substrate 220. The signal lines 226 may branch to multiple locations under the probe substrate 220. Each of the signal lines 226 may be connected to a region called device under test (DUT) (not shown).

The first stiffener 230 and the second stiffener 240 are located opposite each other with the probe substrate 220 interposed therebetween. The first stiffener 230 is referred to as a wafer side stiffener (WSS) because it faces the substrate 20, and the second stiffener 240 is referred to as a tester side stiffener (TSS) because it is located on the side of the tester 300. The first stiffener 230 and the second stiffener 240 can prevent local deformation of the probe substrate 220. For example, the first stiffener 230 and the second stiffener 240 assist to maintain the overall shape of the probe card 200. The first stiffener 230 may electrically connect the signal lines 226 inside the probe substrate 220 to the probe needles 210. Examples of material that can be used to form the first stiffener 230 and second stiffener 240 include stainless steel. Or, the first stiffener 230 includes ceramic material and the second stiffener 240 includes stainless steel.

The probe needles 210 may be formed in the shape of very thin needles such that respective ends thereof contact terminals (i.e., pads) formed in the semiconductor devices of the substrate 20. The probe needles 210 may be fixed to or installed on the first stiffener 230 or the first surface 224 of the probe substrate 220 by an adhesive. The probe needles 210 deliver a test signal transmitted from the tester 300 to the pads of the semiconductor devices. In one embodiment, if the substrate 20 is a wafer including a plurality of semiconductor devices (e.g., semiconductor chips), the probe needles 210 may deliver the test signal simultaneously to the plurality of semiconductor devices.

The coupling pins 250 may be disposed on edges of the second surface 222 of the probe substrate 220. The coupling pins 250 may determine the position of the probe card 200 by physically connecting the probe card 200 to the tester head 100. Thus, the coupling pins 250 are referred to as zero insert force (ZIF). The coupling pins 250 connect the signal lines 226 formed inside the probe substrate 220 to signal lines formed inside the tester head 100. Hence, a test signal generated by the tester 300 can be delivered to the signal lines 226 inside the probe substrate 220.

Referring to FIG. 2, the tester head 100 may be placed on the probe card 200. Specifically, the tester head 100 may include a test board portion 140 and a mother board portion 130. The mother board portion 130 may be directly connected to the probe card 200. The test board portion 140 may include various types of boards 142 manufactured according to characteristics of semiconductor devices to be tested. The mother board portion 130 may serve as a substrate which connects the boards 142 of the test board portion 140 to the probe card 200 and may be referred to as a wafer mother board (WMB).

The mother board portion 130 may include a trench 130t. The trench 130t is formed in a surface of the mother board portion 130 which faces the probe card 200. In a lower part of the mother board portion 130, pogo blocks 132 may be formed on sides of the trench 130t. In this case, a plurality of pogo pins may be provided in each of the pogo blocks 132 and may be electrically connected to the signal lines 226 formed in the probe card 200. Therefore, a test signal generated by the test body 310 and then transmitted to the tester head 100 is delivered to the probe card 200 via the test board portion 140 of the tester head 100 and the pogo pins (not shown) of each of the pogo blocks 132 sequentially. In the drawing, the pogo blocks 132 are formed on both sides of the trench 130t. However, the present invention is not limited thereto. The mother board portion 130 may further include a clamp (not shown) that can be fixed to the head plate 430. As the mother board portion 130 is fixed to the head plate 430, the tester head 100 may be fixed to the prober 400 (see FIG. 1) during the measurement process. In addition, when the mother board portion 130 is fixed to the head plate 430, the probe card 200 can be prevented from being detached from the head plate 430.

Referring to FIG. 2, the sensor 120 for measuring the deformation of the probe card 200 may be placed on the probe card 200, specifically, on the second surface 202 of the probe card, which may include a second surface 222 of the probe substrate 220, and may also include a surface 232 of the second stiffener 240. In one embodiment, the sensor 120 may be placed on the second stiffener 240 to measure the deformation of the probe card 200. The sensor 120 may be placed on a central portion of the probe card 200. However, the position of the sensor 120 is not limited to the above position. Since the central portion of the probe card 200 will be deformed most, the deformation of the probe card 200 can be measured easily when the sensor 120 is placed on the central portion of the probe card 200. However, the sensor 120 can measure the overall deformation of the probe card 200 using the relationship between the degree of deformation of the probe card 200 and the lateral position of the sensor 120 on the probe card 200. Thus, the position of the sensor 120 can vary while still measuring an overall deformation of the probe card 200. In addition, the sensor 120 may be placed in and fixed to the trench 130t formed in the mother board portion 130. The sensor 120 may be, but is not limited to, electrically connected to the tester 300. The sensor 120 may be, for example, a displacement sensor, an interferometer, or the like. The displacement sensor may be specifically a contact-type displacement sensor.

In one embodiment, a case where the sensor 120 is placed on the second surface 202 of the probe card 200 (e.g., on the second surface 222 of the probe substrate 220 or on a surface 232 of the second stiffener 240) and placed in and fixed to the trench 130t is described. However, the present disclosure is not limited to this case. Specifically, if the sensor 120 is a displacement sensor, it should be placed on the second surface 202 of the probe card 200. In this case, the sensor 120 can measure the deformation of the probe card 200. This is because the sensor 120 measures the deformation of the probe card 200 in direct contact with the probe card 200.

However, if the sensor 120 is an interferometer, it can be placed not only on the second surface 202 of the probe card 200 but also on a top surface 412 of the wafer chuck 410. That is, the sensor 120 can be placed on an edge portion of the top surface 412 of the wafer chuck 410 on which the substrate 20 is not mounted. For example, if the sensor 120 is an interferometer using moire interference, it may be placed on the second surface 222 of the probe substrate 220 to measure interference patterns formed on a surface (e.g., 232) of the second stiffener 240 or the second surface 222 of the probe substrate 220. However, the sensor 120 can also be placed on the edge portion of the top surface 412 of the wafer chuck 410 to measure moire interference patterns formed on the first surface 224 of the probe substrate 220 or a surface (e.g., 234) of the first stiffener 230. Once the interference patterns can be measured using the interferometer, they may be analyzed to measure the deformation of the probe card 200. Therefore, if the sensor 120 is an interferometer, it is not necessarily placed on the second surface 222 of the probe substrate 220.

Referring to FIG. 2, the variable load device 110 linked with the sensor 120 is placed on the second surface 222 of the probe substrate 220. For example, in one embodiment, the variable load device 110 is placed on the second stiffener 240 to provide a variable load to the probe card 200. In addition, the variable load device 110 may be placed in and fixed to the trench 130t. In the drawing, the variable load device 110 and the sensor 120 are disposed close to each other in the trench 130t (e.g., a distance approximately the same as, or smaller than, the width of the sensor 120). This may increase the accuracy and simplicity of determining a displacement of the probe card 200. However, the present disclosure is not limited thereto. For example, the sensor 120 may be spaced further apart from the variable load device 110.

In one embodiment, the variable load device 110 is placed on the central portion (e.g., on the very center) of the probe card 200. For example, when the probe card 200 is circular, the variable load device 110 may be placed at the center of the circle. The variable load device 110 adjusts the deformation of the probe card 200, specifically, keeps the probe card 200 substantially flat by providing a load to the probe card 200. Here, the flatness of the probe card 200 may denote the flatness of the probe substrate 220. As discussed herein, “substantially flat” may mean that the probe substrate 220 is completely flat where the radius of curvature of the probe substrate 220 is infinite, but may also encompass fine deformation caused, for example, by small errors or discrepancies (e.g., small errors that may occur during the measurement process).

The variable load device 110 may provide a variable load using, e.g., a motor. The load may be provided in an upward or downward direction. However, the present disclosure is not limited thereto. For example, the variable load device 110 can be any device that has a predetermined reference value and moves in a direction that adds or removes pressure or displacement generated in the variable load device 110.

Since the variable load device 110 adjusts the deformation of the probe card 200 by providing a variable load to the probe card 200, in one embodiment, it is placed on the second surface 202 of the probe card 200. In addition, the variable load device 110 may be placed on the central portion of the probe card 200 in order to effectively provide the variable load to the probe card 200. If the variable load device 110 is not installed on the central portion of the probe card 200, the variable load provided by the variable load device 110 may not be effectively distributed over the probe card 200. Accordingly, this may make it more difficult to adjust the deformation of the probe card 200.

The variable load device 110 and the sensor 120 may be linked with each other as follows. In one embodiment, the tester head 100 is electrically connected to the test body 310 as described above. The sensor 120 may be electrically connected to the variable load device 110 by the test body 310. Deformation information of the probe card 200 measured by the sensor 120 may be sent to the test body 310. Then, the test body 310 may transmit a signal for instructing the variable load device 110 to adjust the deformation of the probe card 200 to the variable load device 110. The sensor 120 and the variable load device 110 may be electrically connected to the test body 310 directly or via the signal lines formed inside the tester head 100. Alternatively, the sensor 120 and the variable load device 110 may be electrically connected to each other without being connected via the test body 310. In this case, the sensor 120 may measure the deformation of the probe card 200 and send a signal corresponding to the measured deformation to the variable load device 110. Then, the variable load device 110 may receive the signal and adjust the deformation of the probe card 200 by providing a variable load corresponding to the received signal to the probe card 200.

In one embodiment, the sensor 120 may be a displacement sensor, and the variable load device 110 may be a variable load motor. For ease of description, the sensor 120, the variable load device 110, and the probe card 200 only are illustrated.

Referring to FIG. 3, the second surface 202 of the probe card 200, for example, a surface 232 of the second stiffener 240, may further include a fixing portion 242 at a position corresponding to the variable load device 110. When the tester head 100 (see FIG. 1) descends to dock with the head plate 430, the fixing portion 242 may be coupled to the variable load device 110, thereby fixing the variable load device 110 in position. For example, the fixing portion 242 may include rigid or semi-flexible members 242a and 242b having flanges that snap or slide into place to allow a bottom connection member 243 of the variable load device 110 to be fixedly secured to the probe card 200. If the probe card 200 is not deformed, the fixing portion 242 may be coupled to the variable load device 110 when the tester head 100 docks with the head plate 430. However, if the probe card 200 is deformed, the fixing portion 242 may be coupled to the variable load device 110 before or after the tester head 110 docks with the head plate 430.

Referring to FIGS. 3 through 4B, the deformation of the probe card 200 may be characterized based on, for example, a height difference of the probe card 200, the radius of curvature of the probe card 200, a bending angle of the probe card 200, or the like. Other characterizations of the probe card may be used to indicate a deformation as well. Further, the deformation of the probe card 200 may be caused by a rapid temperature change during the test process, a high-temperature test, a low-temperature test, or stylus pressure applied by the weight of the probe needles 210 of the probe card 200. Referring to FIG. 4A, the deformation of the probe card 200 may include a height change of the probe card 200. A first point 200a on the probe card 200 may be where the head plate 430 contacts the probe card 200 (e.g., at an edge of the probe card), and a second point 200b on the probe card 200 may have a largest difference in height from the first point 200a. Here, a height difference d of the probe card 200 is a distance between the second point 200b and the first point 200a on the probe card 200. Since the first point 200a is fixed in position by the docking of the tester head 100 with the head plate 430, it can be understood that the first point 200a remains unchanged even if the measurement environment changes. Therefore, the first point 200a can be used as a reference point for measuring the deformation of the probe card 200. Referring to FIG. 4B, the deformation of the probe card 200 may be the radius of curvature of the probe card 200. When the probe card 200 is not deformed, the radius of curvature of the probe card 200 is substantially infinite (e.g., the probe card 200 is substantially flat). However, when the probe card 200 is deformed, the radius of curvature of the probe card 200 changes to a real number value that can be measured by the sensor 120.

Specifically, when the deformation of the probe card 200 is determined based on the height difference of the probe card 200, the sensor 120 (e.g., a displacement sensor or an interferometer) may measure the height difference of the probe card 200. When the sensor 120 is an interferometer, a moire interferometer may be used. However, when the deformation of the probe card 200 is determined based on the radius of curvature of the probe card 200, the sensor 120 may be an interferometer, and not a displacement sensor that can measure a displacement change at a point.

Referring to FIG. 3, the probe card 200 is placed on the head plate 430. The probe needles 210 are provided on the first surface 204 of the probe card 200, and a displacement sensor 122 and a variable load motor 112 are disposed on the second surface 202 which is opposite the first surface 204. The displacement sensor 122 for measuring the deformation of the probe card 200 is connected to the tester 300. Since the variable load motor 112 is located in the central portion of the probe card 200, the displacement sensor 122 may measure the deformation of the probe card 200 in a region outside the central portion. The variable load motor 112 is electrically connected to the displacement sensor 122 by the tester 300 and provides a variable load for adjusting the deformation of the probe card 200 to the probe card 200.

Referring to FIG. 3, the deformation of the probe card 200 may be the height difference of the probe card 200. In one embodiment, what is actually measured by the displacement sensor 122 is the deformation of the second stiffener 240. If the second stiffener 240 disposed on the probe substrate 220 has a uniform thickness, the deformation of the second stiffener 240 can be understood as the deformation of the probe card 200. Specifically, it may be assumed that the thickness of the second stiffener 240 is d1 and that a height from a point where the probe substrate 220 contacts the head plate 430 to a highest point of the second stiffener 240 is d2. In this case, the height difference d of the probe card 200 which corresponds to the deformation of the probe card 200 is a value obtained by subtracting d1 from d2. However, since the displacement sensor 122 is located outside the central portion of the probe card 200, its measurement result may be a value smaller than the value obtained by subtracting d1 from d2. However, since the correlation between the deformation of the probe card 200 and the lateral position of the displacement sensor 120 can be used, for example using simple geometric relationships, the position of the displacement sensor 122 may vary and the height difference d can still be determined. The correlation between the deformation of the probe card 200 and the position of the displacement sensor 120 may be included in the tester 300.

Referring to FIGS. 5A and 5B, using the deformation information of the probe card 200 received from the sensor 120 via the tester 300, the variable load device 110 provides a load to the probe card 200. The provided load can remove the height difference of the probe card 200. When the probe card 200 bulges toward the sensor 120 as shown in FIG. 5A, the tester 300 provides a signal for instructing the variable load device 110 to provide a load in a direction that pushes the probe card 200. In response to the signal, the variable load device 110 may remove the deformation of the probe card 200 by applying a load onto the probe card 200. Conversely, when the probe card 200 sags in a direction away from the sensor 120 as shown in FIG. 5B, the variable load device 110 may remove the deformation of the probe card 200 by applying a load in a direction that pulls the probe card 200.

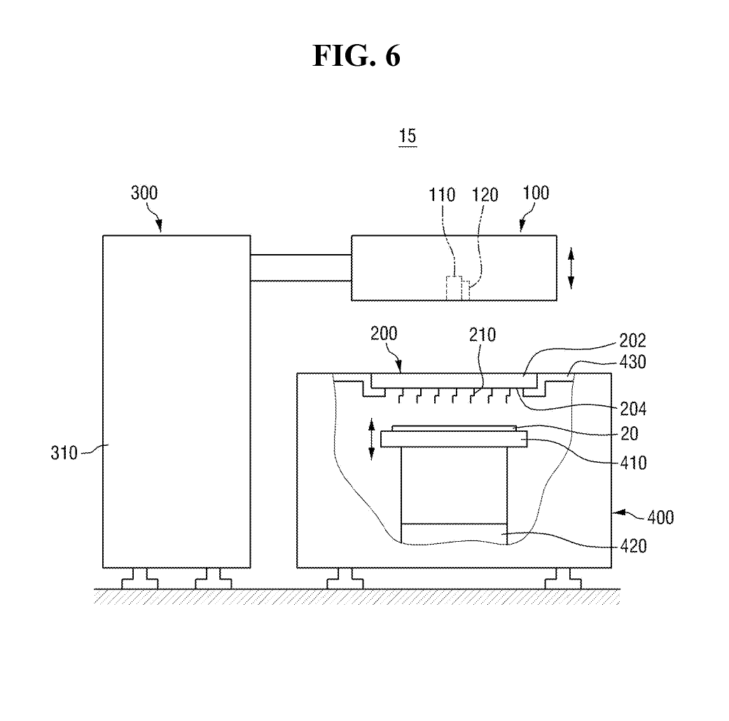

Semiconductor test equipment according to another exemplary embodiment will now be described with reference to FIG. 6. In one embodiment, the test equipment 15 depicted in FIG. 6 is identical to the previous embodiment except that a pressure sensor is further provided under a wafer chuck. Thus, elements substantially identical to those of the previous embodiment are indicated by like reference numerals, and their description will be omitted.

FIG. 6 is an exemplary side view of semiconductor test equipment 15 according to one embodiment.

Referring to FIG. 6, the semiconductor test equipment 15 includes a tester 300, a prober 400, a sensor 120, a variable load device 110, and a probe card 200. The prober 400 may further include a pressure sensor 420 installed under a wafer chuck 410. The pressure sensor 420 may be electrically connected to the tester 300. The pressure sensor 420 measures pressure (i.e., stylus pressure) created between probe needles 210 and semiconductor devices formed on a substrate 20 to be tested.

When the pressure sensor 420 is absent, the wafer chuck 410 on which the substrate 20 is mounted ascends a predetermined distance such that the probe needles 210 contact the substrate 20. After the probe needles 210 contact the substrate 20, the substrate 20 is further raised by a predetermined distance in order to create a contact force greater than a predetermined level between the probe needles 210 and the substrate 20. As a result, the wafer chuck 410 over-drives the substrate 20 by a predetermined distance, regardless of the contact force between the probe needles 210 and the substrate 20.

However, the contact force between the probe needles 210 and the substrate 20 acts as an important factor in the semiconductor device testing process. Therefore, the pressure sensor 420 may be installed under the wafer chuck 410 to measure the contact force between the probe needles 210 and the substrate 20 in real time. If the wafer chuck 410 is raised or lowered by reflecting the measurement value of the pressure sensor 420, semiconductor devices can be tested more effectively. Here, if the pressure sensor 420, the sensor 120 and the variable load device 110 are linked with each other, the probe card 200 can remain flat, and, at the same time, the contact force between the probe needles 210 and the substrate 20 can be maintained constant at a predetermined level.

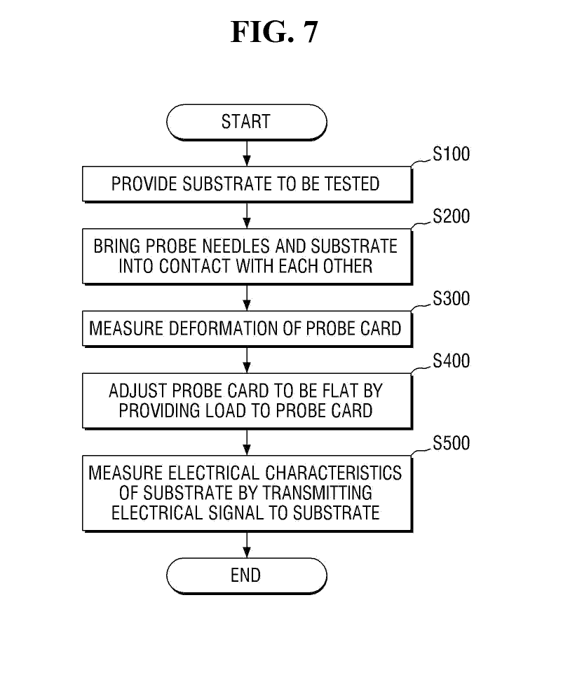

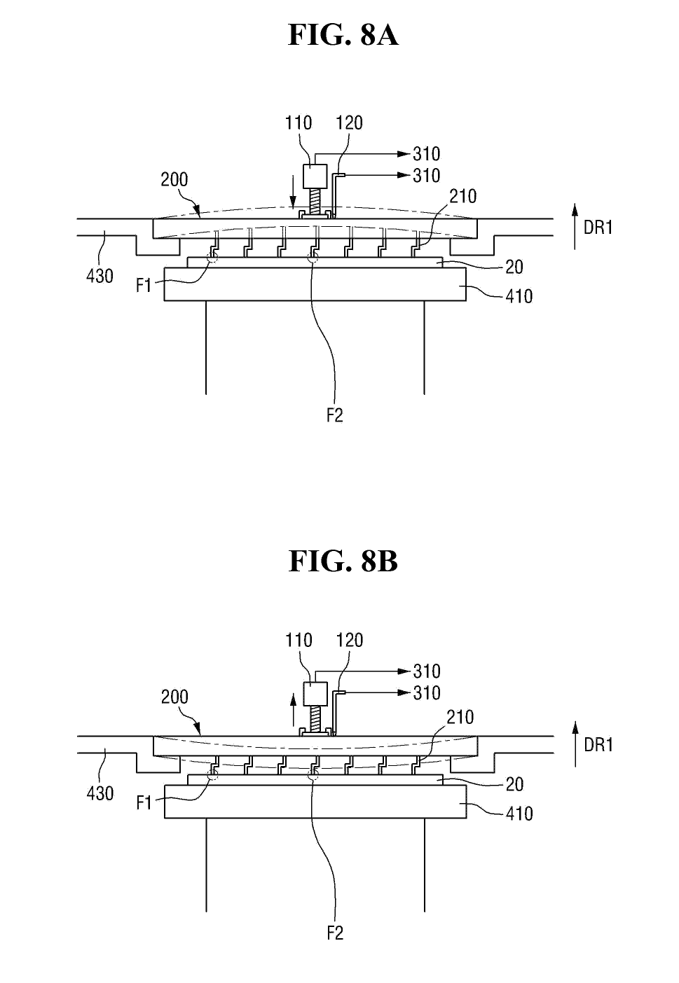

An exemplary method of testing semiconductor devices according to one embodiment will now be described with reference to FIGS. 7 through 8B.

FIG. 7 is a flowchart illustrating an exemplary method of testing semiconductor devices according to one embodiment. FIGS. 8A and 8B are exemplary side views illustrating intermediate processes included in the test method of FIG. 7.

Referring to FIGS. 2 and 7, a substrate 20 to be tested is provided on a wafer chuck 410 (operation S100). The substrate 20 may be, but is not limited to, in an on-wafer state, that is, may not yet have been separated into semiconductor chips. Alternatively, the substrate 20 may include a single chip or may be part of a single stack of chips. Before the substrate 20 is provided, a value (i.e., a reference value) of displacement or radius of curvature of a probe card 200 in a case where the probe card 200 is substantially flat may be input to a sensor 120. However, the present disclosure is not limited thereto.

Referring to FIG. 2, a tester head 100 and a head plate 430 are docked and thus fixed to each other. Here, the probe card 200 and the tester head 100 are also fixed in position, and the probe card 200 may be electrically connected to the tester head 100. After the tester head 100 and the head plate 430 are fixed to each other, first deformation of the probe card 200 may be measured. For example, to measure electrical characteristics or reliability of semiconductor devices at a high or low temperature using semiconductor test equipment, the semiconductor test equipment may be set to a temperature required for the measurement, and the set temperature may cause the probe card 200 to be deformed. However, the process of measuring the first deformation of the probe card 200 can be omitted.

Specifically, the sensor 120 may measure the first deformation of the probe card 200, and a variable load device 110 linked with the sensor 120 may provide a load to the probe card 200 according to first deformation information of the probe card 200. The load provided by the variable load device 110 acts on a second stiffener 240, a probe substrate 220, and a first stiffener 230 sequentially. Accordingly, a top surface of the probe substrate 220, that is, the probe card 200 can be adjusted to be flat.

Referring to FIGS. 2 and 7 through 8B, probe needles 210 and the substrate 20 are brought into contact with each other (operation S200). A first contact force is created between the probe needles 210 on a surface of the probe card 200 which faces the wafer chuck 410 and semiconductor devices on the substrate 20. Here, the first contact force may be a contact pressure needed between the probe needles 210 and the substrate 20 to measure the electrical characteristics and reliability of the semiconductor devices.

To bring the probe needles 210 and the substrate 20 into contact with each other, the wafer chuck 410 is raised. Accordingly, the substrate 20 mounted on the wafer chuck 410 may make a first contact with the probe needles 210. The first contact denotes a contact made when the substrate 20 has just reached the probe needles 210. However, the first contact between the substrate 20 and the probe needles 210 may not be enough to obtain a sufficient contact force to test the semiconductor devices. Therefore, after the first contact, the wafer chuck 410 may be raised further by a predetermined distance, causing the substrate 20 to make a second contact with the probe needles 210. When the substrate 20 and the probe needles 210 make the second contact with each other, it means that a first contact force has already been created between the substrate 20 and the probe needles 210.

In FIGS. 8A and 8B, portions indicated by dotted lines represent the probe card 200 after the probe needles 210 and the substrate 20 are brought into contact with each other. The probe card 200 may be deformed by the stylus pressure of the probe needles 210 and/or temperature changes. Here, a contact force F1 may be created between the probe needles 210 and an edge region of the substrate 20, and a contact force F2 may be created between the probe needles 210 and a central portion of the substrate 20. Since the head plate 430 is an element fixed to a prober 150 (see FIG. 1), the position of the head plate 430 is hardly changed by the stylus pressure of the probe needles 210 and/or temperature changes. Therefore, the head plate 430 may operate according to the set value of the semiconductor test equipment, and thus F1 may be a first contact force. Accordingly, F2 created between the probe needles 210 and the central portion of the substrate 20 may be a second contact force. Since the probe card 200 has been deformed, the first contact force and the second contact force may be different from each other. In FIG. 8A, the second contact force is smaller than a contact force (i.e., the first contact force) required to test the semiconductor devices. Conversely, in FIG. 8B, the second contact force is greater than the contact force required to test the semiconductor devices. When the second contact force is greater or smaller than the first contact force required to test the semiconductor devices, the reliability of the semiconductor device testing process may be reduced, resulting in a reduction in yield. Therefore, in certain embodiments, the deformation of the probe card 200 is adjusted such that the contact force F2 created between the probe needles 210 and the central portion of the substrate 20 becomes the first contact force.

The deformation of the probe card 200 can be caused not only by the physical contact of the substrate 20 with the probe needles 210 but also by local heat generated from the semiconductor devices during the process of measuring the semiconductor devices.

Referring to FIGS. 7 through 8B, second deformation of the probe card 200 in contact with the substrate 20 is measured (operation S300). The variable load device 110 linked with the sensor 120 may provide a load to the probe card 200 according to second deformation information of the probe card 200. Accordingly, the top surface of the probe substrate 220, and as a result, the probe card 200 can be adjusted to be flat (operation S400). The load provided by the variable load device 110 acts on the second stiffener 240, the probe substrate 220, and the first stiffener 230 sequentially, thereby making the probe card 200 flat.

In the process of adjusting the probe card 200 to be flat, the contact force F2 created between the probe needles 210 and the central portion of the substrate 20 may be adjusted from the second contact force inappropriate for measuring semiconductor devices to the first contact force. As described above, the first contact force is the contact pressure needed between the probe needles 210 and the substrate 20 to measure the electrical characteristics and reliability of semiconductor devices.

Referring to FIGS. 7 and 8A, after the first contact force is induced between the probe needles 210 and the substrate 20 by adjusting the probe card 200 to be flat, an electrical signal is input to the substrate 20, i.e., the semiconductor devices on the substrate 20 via the probe needles 210 to measure the electrical characteristics of the semiconductor devices on the substrate 20 (operation S500). The electrical signal provided through the probe needles 210 may be a test signal for testing the electrical characteristics and reliability of each of the semiconductor devices. Signals output from the semiconductor devices in response to the input signal may be analyzed to determine whether the semiconductor devices are defective, and the semiconductor devices may be repaired if they are defective.

While the semiconductor devices are being tested, the probe card 200 may be deformed by local heat generated from the semiconductor devices. In this case, the sensor 120 measures the deformation of the probe card 200 and sends deformation information of the probe card 200 to the variable load device 110 linked with the sensor 120. Then, the variable load device 110 adjusts the probe card 200 to be flat by providing a load to the probe card 200 according to the received deformation information of the probe card 200. As such, the deformation of the probe card 200 can be adjusted in real time to ensure that throughout the testing process, the probe card 200 remains substantially flat.

In one embodiment, the substrate described above includes a plurality of semiconductor chips formed in an array as part of a wafer. For example, the wafer may include a single layer of chips, or a plurality of layers of chips stacked on each other. Each chip or stack of chips may be referred to as a semiconductor device. In another embodiment, the substrate refers to a singulated chip or stack of chips. Each chip or stack of chips may be referred to as a semiconductor device. The chips may include an integrated circuit, as well as different layers, internal wiring, chip pads, and other components. If the chips are tested as part of a wafer, they may be singulated after testing, at which point they may be included in a semiconductor device, such as a semiconductor package. If the chips are tested individually in singulated form, they also may be included in a semiconductor device after testing.

For example, in one embodiment, a substrate 20 may include a plurality of stacked wafers that form a plurality of adjacent chip-stacks. After testing, the chip-stacks may be singulated and included in chip-stack packages (e.g., that include a package substrate, the chip-stack, various wiring and/or through-substrate via (TSV) connections, and encapsulation). If the substrate 20 includes a single wafer including only a single layer of chips, after testing, the chips may be singulated and included in a chip-stack packages, or may be stacked with another wafer, which may be tested again in stacked form, prior to either further stacking or singulation and inclusion in a chip-stack package. As a result, in the above-described examples, a substrate 20 is tested, and after testing, it is used to form a semiconductor device (e.g., a singulated chip or stack of chips, a chip package or chip stack package, etc.). The semiconductor devices may be included in a card, a semiconductor module, an electronic system, etc.

The semiconductor devices may be memory devices, which may include a volatile memory device such as a dynamic random access memory (DRAM) and a static random access memory (SRAM), a non-volatile memory device such as a flash memory, a phase change memory, a magnetic random access memory (MRAM), or a resistive random access memory (RRAM), or a combination of thereof. Alternatively, the semiconductor devices may be logic devices, such as microprocessors, controllers, etc.

The semiconductor devices may be included in an electronic system, for example, including a controller, an input and output device, a memory device, an interface, a bus, etc. The electronic system may be implemented, for example, as a memory card, a mobile system, a personal computer, an industrial computer, or another logic system that can perform various functions. For example, the mobile system may be any one of a personal digital assistant (PDA), a portable computer, a web tablet, a mobile phone, a wireless phone, a laptop computer, a memory card, a digital music system, and an information transmitting/receiving system. If the electronic system is an apparatus that can perform wireless communication, the electronic system may be used in a communication system such as a Code Division multiple Access (CDMA), a Global System for Mobile communication (GSM), a North American Digital Cellular (NADC), an Enhanced-Time Division Multiple Access (E-TDMA), a Wideband Code Division Multiple Access (WCDMA), or a CDMA 2000.

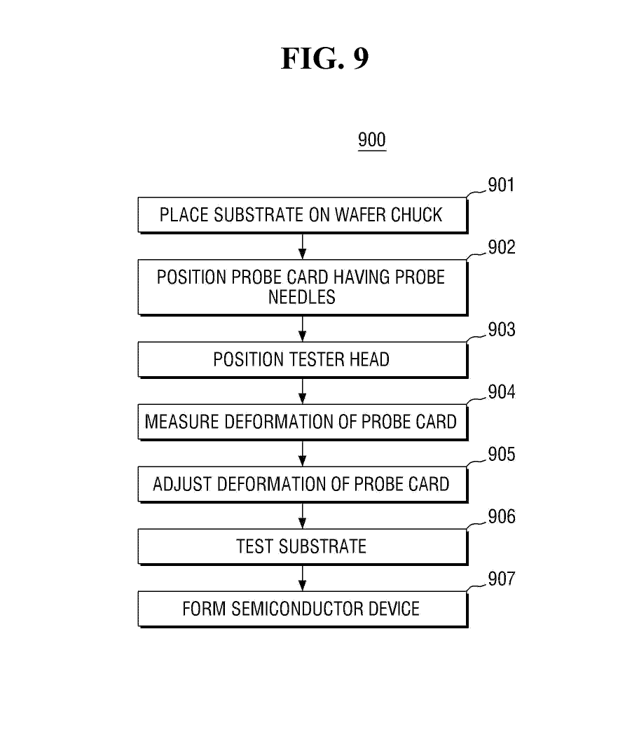

FIG. 9 is a flow chart of an exemplary method 900 of manufacturing a semiconductor device, according to certain embodiments.

In step 901, a substrate is placed on a wafer chuck. The substrate may be, for example, a wafer substrate or a singulated substrate, such as discussed above. The substrate maybe placed on the wafer chuck in one or more of the manners discussed above (e.g., using a vacuum and transfer process). In step 902 a probe card having probe needles is positioned above the substrate. For example, the probe card and probe needles can have a structure such as described previously. In step 903, a tester head is positioned above the probe card. The tester head may have a structure and operation such as described previously. Though steps 901 through 903 are depicted in a particular order, they do not need to occur in that order. For example, the substrate can be placed on the wafer chuck after the probe card, wafer chuck, and tester head are appropriately positioned.

In step 904, a deformation of the probe card is measured. For example, in one embodiment, the tester head is moved (e.g., lowered) to be coupled with the probe card, at which point the deformation of the probe card is measured. In another embodiment, the tester head is coupled with the probe card and the wafer chuck is raised until the probe needles contact the substrate, at which point the deformation of the probe card is measured. The deformation may be measured using a sensor. For example, a sensor may be disposed above the probe card in order to measure the deformation of the probe card. The sensor may measure, for example, a height difference of the probe card, or a radius of curvature of the probe card. Thus, one or more of the embodiments described above may be used to measure the deformation of the probe card.

In step 905, the deformation of the probe card is adjusted. For example, using a variable load device 110 such as described in the various embodiments above, a deformation of the probe card can be adjusted. In one embodiment, a variable load device used to make the adjustment is linked to the sensor that measures the deformation of the probe card. In one embodiment, the deformation is adjusted so that the probe card becomes substantially flat.

In step 906, after the deformation is adjusted, the substrate is tested. For example, test signals may be transmitted from a tester through the tester head, the probe card, and the probe needles to the substrate, and test results may be transmitted from the substrate to the tester. The testing may determine whether the semiconductor device or devices that form the substrate operate properly.

In step 907, a final semiconductor device is formed. For example, if the substrate was an array of chips, or a stacked array of stacked chips, after testing, the chips or stacks of chips may be singulated to form individual semiconductor devices. After singulation, or in the case where the substrate was already a singulated device, the chips or stacks of chips may be further processed to be combined with other chips or with other substrates, for example, to form semiconductor devices in the form of semiconductor packages. Each package may include, for example, wire bonds, TSVs, encapsulation, etc. Other types of semiconductor devices may also be formed after the testing is complete.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

1. A method of manufacturing a semiconductor device including a substrate, the method including:
providing the substrate on a wafer chuck;
positioning a probe card having probe needles above the substrate;
positioning a tester head above the probe card;
using a sensor included in the tester head, measuring a deformation of the probe card;
using a variable load device included in the tester head, adjusting the deformation of the probe card based on the measured deformation; and
testing the substrate using the adjusted probe card.

2. The method of claim 1, further comprising:
including the sensor and the variable load device in a trench formed in the tester head.

3. The method of claim 2, wherein:
the trench is formed at a central portion of the tester head.

4. The method of claim 3, wherein:
the sensor and variable load device are adjacent each other and are fixed in the trench.

5. The method of claim 2, further comprising:
in order to measure the deformation of the probe card, moving the tester head toward the probe card until the variable load device is secured to a fixing portion disposed on a surface of the probe card.

6. The method of claim 5 1, further comprising:
measuring the deformation of the probe card by measuring a height difference of the probe card or a radius of curvature of the probe card.

7. The method of claim 1, further comprising:
adjusting the deformation of the probe card by providing a load to the probe card by the variable load device in order to cause the probe card to be substantially flat.

8. The method of claim 1, further comprising:
using a pressure sensor disposed under the wafer chuck to measure a pressure between the substrate and the probe needles.

9. The method of claim 1, wherein the substrate is a wafer substrate including a plurality of semiconductor chips formed in an array.

10. The method of claim 9, further comprising:
after testing the substrate, singulating at least one of the semiconductor chips from the wafer.

11. A method of manufacturing a semiconductor device, comprising:
placing a substrate used to form the semiconductor device on a wafer chuck;
positioning a probe card having probe needles above the substrate;
positioning a tester head above the probe card;
using a sensor disposed above the probe card, measuring a deformation of the probe card;
using a variable load device disposed above the probe card, and based on the measurement, causing the probe card to be substantially flat;
testing the substrate using the substantially flat probe card; and
forming the semiconductor device after testing of the substrate is complete.

12. The method of claim 11, further comprising:
including the sensor and the variable load device in a trench formed in the tester head.

13. The method of claim 12, wherein:
the trench is formed at a central portion of the tester head.

15. The method of claim 12, further comprising:
in order to measure the deformation of the probe card, moving the tester head toward the probe card until the variable load device is secured to a fixing portion disposed on a surface of the probe card.

16. The method of claim 11, further comprising:
measuring the deformation of the probe card by measuring a height difference of the probe card or a radius of curvature of the probe card.

17-20. (canceled)
